(19) United States
(12) Patent Application Publication
(10) Pub. No.: US 2025/0376756 A1
(43) Pub. Date: Dec. 11, 2025

(54) APPARATUS AND METHOD FOR PULSED LASER DEPOSITION

(71) Applicant: SONGSHAN LAKE MATERIALS LABORATOR, Dongguan City (CN)

(72) Inventors: Zhongpei Feng, Dongguan City (CN); Kui Jin, Dongguan City (CN); Jie Yuan, Dongguan City (CN); Bo Xu, Dongguan City (CN); Zhongxian Zhao, Dongguan City (CN); Jingting Yang, Dongguan City (CN)

(21) Appl. No.: 18/840,483

(22) PCT Filed: Dec. 29, 2022
(86) PCT No.: PCT/CN2022/143318

§ 371 Date: Apr. 14, 2025

(30) Foreign Application Priority Data
Feb. 21, 2022 (CN) 202210155728.6
Feb. 21, 2022 (CN) 202210155960.X
Jul. 29, 2022 (CN) 202210906042.6

(51) Int. Cl. C23C 14/34; C23C 14/04; C23C 14/50; C23C 14/54

(52) U.S. Cl. CPC C23C 14/3485; C23C 14/042; C23C 14/505; C23C 14/545

(57) ABSTRACT

The present application discloses an apparatus for pulsed laser deposition and method. The device includes a laser scanning sputtering component comprising: a base; an adjustment device located on the base; multiple second supports located on the adjustment device and extending in the third direction; a first support located on the multiple second supports. The adjustment device adjusts the second supports and the first support to move in the first direction and/or the second direction, the first direction, the second direction, and the third direction being mutually perpendicular. The apparatus for pulsed laser deposition and method provided by the present disclosure enable precise control of the irradiation time of the laser beam on the target material surface through the laser scanning sputtering component, thereby not only improving the rate for depositing a film but also enhancing the performance of a single-component film and a combinatorial film.

This application claims priority to the Chinese invention application No. 202210155728.6 filed on Feb. 21, 2022, entitled “COMBINATORIAL FILM PREPARATION METHOD AND DEVICE”, the Chinese invention application No. 202210155960.X filed on Feb. 21, 2022, entitled “COMBINATORIAL FILM PREPARATION METHOD AND DEVICE” and the Chinese invention application No. 202210906042.6 filed on Jul. 29, 2022, entitled “LASER SCANNING SPUTTERING COMPONENT”, the contents of which are and incorporated herein by reference, including all of the specifications, claims, drawings, and abstracts.

### TECHNICAL FIELD

The present disclosure relates to a field of thin film deposition technology, particularly to an apparatus and a method for pulsed laser deposition.

### BACKGROUND

Superconducting films made into antennas, resonators, filters, delay lines, and other microwave communication devices have unmatched high sensitivity compared to conventional materials (such as gold, silver, etc.), which has attracted the attention of military forces around the world and become a key technology in future electronic warfare, as well as the “future” of new generation communication technology. In large particle accelerators, superconducting films also show great market prospects.

Pulsed Laser Deposition (PLD) technology, as an important technique for preparing superconducting films, generates plasma in the direction normal to the target material through the interaction of the laser with the target material, and the plasma nucleates on the surface of the substrate to grow into a film.

In the pulsed laser deposition process, combinatorial films are films composed of different components. Films with various functions, such as superconducting, ferroelectric, and dielectric materials with rich phase transitions, can be obtained by selecting precursor materials. Due to their rich material phase diagrams and broad application prospects, they have also become a focus in the industry. In existing technologies, combinatorial laser molecular beam epitaxy technology is often used to prepare combinatorial films. Combinatorial laser molecular beam epitaxy technology uses target materials made of different materials, and by bombarding the corresponding target materials with excimer lasers, the corresponding precursor components are sputtered, thus depositing the precursor components on the substrate. By periodically sputtering different materials of target materials, combinatorial films are formed on the substrate.

In existing technologies, when depositing combinatorial films, two methods are usually adopted: one is to achieve the deposition of different components by replacing target materials; the other is to install multiple target materials at the same time and achieve the deposition of different components by changing the target materials bombarded by the laser beam. However, both methods have some problems: on the one hand, replacing target materials requires time and may also introduce thermal disturbance, causing the deposited film to be repeatedly annealed, reducing the performance of the combinatorial film; on the other hand, by controlling the deposition time between the plume body formed by the laser beam irradiating the target material and the substrate through a mask, the film deposition on different deposition areas of the substrate is controlled, which leads to uneven film thickness distribution in the deposition of large-sized combinatorial films; in addition, the presence of multiple target materials at the same time is also prone to mutual contamination of target materials.

### SUMMARY OF THE DISCLOSURE

In view of the above problems, an objective of the present disclosure is to provide an apparatus and a method for pulsed laser deposition that can achieve precise control of the irradiation time of the laser beam on the target material surface through a laser scanning sputtering component, thereby not only improving the deposition rate of a film but also improving the performance of a single-component film and a combinatorial film.

According to one aspect of the present disclosure, an apparatus for pulsed laser deposition is provided, which includes a deposition device and multiple laser scanning sputtering components. The laser scanning sputtering components include: a base; an adjustment device, located on the base; multiple second supports, located on the adjustment device, extending in the third direction; a first support, located on the multiple second supports; wherein the adjustment device adjusts the second supports and the first support to move in the first direction and/or the second direction, the first direction, the second direction, and the third direction are mutually perpendicular to each other.

Optionally, the adjustment device includes: a first plate and a second plate; a fastener, fixed on the first plate, for fixing the second supports and the adjustment device; a first sliding member, being slidable and fixing the first plate and the second plate, located between the first plate and the second plate, to enable the first plate and the second plate to move relatively in the first direction; a second sliding member, being slidable and fixing the second plate and the base, located between the second plate and the base, to enable the second plate and the base to move relatively in the second direction.

Optionally, the adjustment device further includes: a first adjustment member, connected to the first sliding member, for controlling the first plate and the second plate to move relatively in the first direction with high-precision automated displacement scanning control; a second adjustment member, connected to the second sliding member, for controlling the second plate and the base to move relatively in the second direction with high-precision automated displacement scanning control.

Optionally, the multiple second supports are adjustable supports.

Optionally, the adjustment device further includes: a third adjustment member, connected to the second supports, for adjusting the length of the second supports in the third direction to adjust the tilt angle of the first support.

Optionally, the multiple second supports are equipped with a fourth adjustment member, for adjusting the length of the second supports in the third direction to adjust the tilt angle of the first support.

Optionally, the first adjustment member, the second adjustment member, and/or the third adjustment member include a high-precision precision motor.

Optionally, the first adjustment member, the second adjustment member, and/or the third adjustment member are used to control the scanning path and scanning rate of a laser beam generated by a laser on the target material.

Optionally, the deposition device includes: a reaction chamber, a target holder and a substrate holder, and the target holder and the substrate holder are set opposite to each other inside the reaction chamber. The target holder is used for installing the target material, and the substrate holder is used for installing the substrate, wherein the laser scanning sputtering components control the scanning rate of the laser beam on the scanning path to change the deposition time for different deposition areas on the substrate, thereby controlling the content of the deposited material corresponding to the component of the target material on different deposition areas of the substrate.

Optionally, the target holder is equipped with multiple target materials, the components of the deposited materials of the multiple target materials are the same or different, a mask is set on the target holder, the mask forms a side wall on the target holder to separate the plumes generated by adjacent ones of the multiple target materials during sputtering, the mask extends to a vicinity of the substrate holder to separate multiple deposition areas of the substrate, the mask and the substrate holder move relatively to change the exposure deposition time for different deposition areas of the substrate, thereby controlling the content of the deposited material corresponding to different components of the multiple different target materials on different deposition areas of the substrate, thus forming a combinatorial film of the components of the deposited materials of the multiple target materials on the substrate.

Optionally, the combinatorial film includes: a combinatorial film with deposited material components varying in a linear gradient or a non-linear gradient; and a multi-layer heterojunction combinatorial film with deposited material components deposited alternately.

Optionally, the deposition device further includes: a control structure, one end of which is fixedly connected to the target holder and the other end is connected to the mask, for controlling the mask to move relatively to the substrate holder.

Optionally, the target holder and the substrate holder are stationary, and the mask is moved to change the deposition time for different deposition areas of the substrate.

Optionally, the mask moves reciprocally in a gradient changing direction of the deposited material components.

Optionally, the control structure is further configured to control the mask to move in a direction perpendicular to the surface of the substrate.

Optionally, the substrate holder is stationary, and the target holder is moved, driving the mask to move to change the deposition time for different deposition areas of the substrate.

Optionally, the target holder moves reciprocally in a gradient changing direction of the deposited material components.

Optionally, the target holder and the mask are stationary, and the substrate holder is moved to change the deposition time for different deposition areas of the substrate.

Optionally, the substrate holder moves reciprocally in a gradient changing direction of the deposited material components.

Optionally, the apparatus further includes: a laser, located on the first support, for generating a laser beam.

Optionally, the laser is equipped with an indicator light, an indicator light beam generated by the indicator light is parallel to the laser beam, for adjusting an alignment of the laser.

Optionally, the laser beam generated by the laser has wavelengths including 1064 nm, 532 nm, 355 nm, 266 nm, and different wavelengths can be automatically selected and switched.

Optionally, multiple lasers are alternately activated or simultaneously activated.

Optionally, the deposition device further includes: a motor group, located outside the reaction chamber, connected to the target holder and the substrate holder, for controlling movements of the target holder and the substrate holder.

Optionally, the motor group is configured to control the target material to rotate around its center to change a spot position of the laser beam on the target material.

Optionally, the base includes: a support frame, connected to the adjustment device;

a wheel, located at a bottom of the support frame, for moving the laser scanning sputtering components.

Optionally, the wheel has an open state and a locked state, in the open state, the laser scanning sputtering components are allowed to move; in the locked state, the laser scanning sputtering components are not allowed to move.

Optionally, it further includes: a laser power supply, fixed in the support frame, for supplying power to the laser.

According to another aspect of the present disclosure, a method for pulsed laser deposition is provided, and includes: installing at least one target material on a target holder and installing a substrate on a substrate holder; using at least one laser beam to bombard the at least one target material to produce a deposited material; controlling a scanning rate of the at least one laser beam on a scanning path to change a deposition time for different deposition areas on the substrate, thereby controlling a content of the deposited material corresponding to a component of the at least one target material on different deposition areas of the substrate, forming a film with thickness varying in any direction on a surface of the substrate.

Optionally, after a step of controlling the scanning rate of the at least one laser beam on the scanning path to change the deposition time for different deposition areas on the substrate, the method further comprises: replacing the target material, repeating the above-mentioned deposition process, thereby forming a combinatorial film of deposited materials from multiple different target materials on the substrate.

Optionally, the target holder is equipped with multiple target materials, the multiple target materials corresponding to at least a part of the deposition areas of the substrate, and adjacent ones of the multiple target materials are isolated by a mask.

Optionally, the mask is fixed on the target holder, and forms a side wall on the target holder to separate the adjacent ones of the multiple target materials; the mask extends to a vicinity of the substrate holder to separate the deposition areas of the substrate; the mask and the substrate holder move relatively to change the deposition time for different deposition areas of the substrate, thereby controlling the content of the deposited material corresponding to different components of the multiple target materials on different deposition areas of the substrate, thus forming a combinatorial film of the deposited materials of the multiple target materials on the substrate.

Optionally, when the scanning path of the laser beam corresponds to a radius or diameter of the substrate, the scanning rate of the laser beam on the scanning path is gradually increased and/or gradually decreased.

Optionally, the content of the deposited material on the substrate varies continuously along the radius or diameter of the substrate.

Optionally, the substrate rotates around its center to change the deposition areas corresponding to the plurality of target materials.

Optionally, a movement pattern of the substrate rotating around its center includes the movement direction and the movement speed, the movement direction includes: clockwise rotating direction, counterclockwise rotating direction; the movement speed includes: uniform rotating speed, non-uniform rotating speed.

Optionally, the scanning path of the laser beam extends in at least one direction along the surface of the target material.

Optionally, a change pattern of the scanning rate of the laser beam on the scanning path includes at least one of increasing and decreasing.

Optionally, the laser beam includes a plurality of laser beams, and when a corresponding target material among the plurality of target materials is in a sputtering position relative to the substrate, the plurality of laser beams alternately bombard or simultaneously bombard the corresponding target material.

Optionally, when a deposition area of the first target material among the plurality of target materials relative to the substrate changes continuously, an amount of deposited material on the substrate changes with a continuous change of the deposition areas, thereby forming a first film with continuously changing thickness.

Optionally, when a deposition area of the second target material among the plurality of target materials relative to the substrate changes continuously, an amount of deposited material on the substrate changes with the continuous change of the deposition areas, thereby forming a second film with continuously changing thickness.

Optionally, the method further includes: annealing the first film and the second film to form a third film of mixed components of the first film and the second film.

According to the apparatus for pulsed laser deposition provided by the present disclosure, the laser scanning sputtering component uses an adjustable support to fix the laser, which can change an incidence direction of the laser (including an incidence angle and an incidence position), thereby directly irradiating the target material in the reaction chamber for thin film deposition. The extremely simple straight light path greatly reduces the loss of laser energy, and the “overall moving scanning” working mode of the laser light path component provides extremely high stability and consistency for laser scanning sputtering.

Furthermore, the laser may be a small solid-state laser with a small volume and light weight. The laser with low power used in this application can reduce the cost of the equipment and also reduce the volume of the equipment.

In the laser scanning sputtering component of this application, due to the use of a small laser, the weight of the entire laser scanning sputtering component is very small, which allows the entire laser scanning sputtering component to be conveniently controlled in a predetermined direction with an automated high-precision displacement scanning control through the assembly of high-precision precision motors. In addition, since the laser can use a small solid-state laser weighing about 25 kilograms, the process of controlling the laser to move in the first direction and the second direction through the adjustment device is also more convenient, which can also improve the consistency of laser energy at different scanning points on the target material surface during the scanning process.

Furthermore, in the laser scanning sputtering component of this application, the laser is equipped with an indicator light that can produce an indicator light beam, which is convenient for adjusting the tilt angle and moving direction of the laser.

Furthermore, the modular design of the laser scanning sputtering component not only has higher technical compatibility and flexibility but also achieves the purpose of quick assembly and disassembly of the entire system.

Furthermore, according to the apparatus and the method for pulsed laser deposition provided by the present disclosure, in the process of depositing a single-component film or a combinatorial film with a large area, by controlling the scanning rate of the laser beam scanning the target material, the deposition time for different deposition areas on the substrate can be controlled, thereby controlling the thickness distribution of the film, compensating for the deposition of thinner parts of the film, and thus improving the performance of the single-component film or the combinatorial film.

Furthermore, using the method for pulsed laser deposition according to embodiments of the present disclosure various combinatorial films can be formed, including a combinatorial film with thickness gradients changing along the radial direction of the substrate, as well as a combinatorial film with thickness gradients changing in other directions. At the same time, by controlling the scanning rate of the laser beam scanning the target material through the laser scanning sputtering component, the thickness distribution of the combinatorial film can be controlled, and the performance of the combinatorial film can be improved.

Furthermore, according to the apparatus for pulsed laser deposition provided by the present disclosure, the target holder can hold one or more target materials. Multiple target materials are placed side by side, with multiple laser beams and a mask placed vertically between adjacent target materials. By controlling the relative movement of the mask and the substrate, the materials of multiple target materials can be alternately deposited on the substrate to form a combinatorial film, or multiple materials can be deposited at the same time to form a combinatorial film, thereby saving the time for replacing target materials and improving the performance of the combinatorial film.

Furthermore, in this application, the mask located between the target materials forms side walls on the target holder to separate the plasma plumes formed by multiple target materials, preventing mutual contamination between the two target materials. Moreover, the mask can extend to the vicinity of the substrate holder, dividing the substrate into multiple different deposition areas. By controlling the relative movement of the mask and the substrate, the deposition time for different deposition areas can be different, as well as controlling the diffusion range of the plasma plume, making the content variation of the formed combinatorial film show a gradient change, thereby improving the performance of the combinatorial film.

Furthermore, the mask extends vertically from the substrate surface, and during the process of forming the deposited material of different components of multiple target materials on the substrate surface, the mask will not be located between the target material and the substrate. Therefore, the combinatorial film prepared by this application greatly reduces the thermal interference situation brought by the mask parallel to the substrate surface during the movement process in the existing technology, thereby improving the performance of the combinatorial film.

Furthermore, based on the miniaturization of the laser scanning sputtering component according to the present disclosure, it is also possible to use multiple lasers to bombard the target material at the same time to form a combinatorial film. In the preparation process of a combinatorial film, the components of various materials begin to diffuse, making the diffusion of various components in the formed combinatorial film more uniform.

Furthermore, the apparatus and method for pulsed laser deposition according to the present disclosure can also meet requirements for the preparation of combinatorial films with component gradients by co-sputtering methods with multiple target materials (three or more). By retracting the mask vertical to the adjacent target materials or increasing the distance between the mask and the substrate holder, in addition, the method of alternating sputtering deposition can also be used to prepare a multi-layer heterojunction superlattice combinatorial film. Therefore, the present disclosure can not only manufacture single-component uniform films, multi-layer structure films, and various types of combinatorial films, but also improve efficiency and quality.

### BRIEF DESCRIPTION OF THE DRAWINGS

The above and other objects, features, and advantages of the present invention will be more clearly understood through the following description of the embodiments of the disclosure with reference to the accompanying drawings, in which:

FIGS. 1a to 1d show a combinatorial film preparation method and device according to an existing technology;

FIG. 2 shows a thickness distribution diagram of the combinatorial film according to the existing technology;

FIG. 3 shows a three-dimensional view of an apparatus for pulsed laser deposition according to an embodiment of the present disclosure;

FIG. 4 shows a side view of the laser scanning sputtering component according to an embodiment of the present disclosure;

FIG. 5 shows an adjustment device of the laser scanning sputtering component according to an embodiment of the present disclosure;

FIG. 6 shows a schematic diagram of a method for pulsed laser deposition according to an embodiment of the present disclosure;

FIGS. 7a and 7b show a deposition diagram of a combinatorial film in a first embodiment of the present disclosure;

FIGS. 8a and 8b show a top view and a cross-sectional view of the combinatorial film in the first embodiment of the present disclosure;

FIG. 9 shows a deposition diagram of a combinatorial film in a second embodiment of the present disclosure;

FIG. 10 shows a top view of the combinatorial film in the second embodiment of the present disclosure;

FIG. 11 shows a thickness distribution diagram of a combinatorial film in an embodiment of the present disclosure;

FIGS. 12a to 12d show stage diagrams of a combinatorial film preparation method according to a third embodiment of the present disclosure;

FIGS. 13a and 13b show stage diagrams of a combinatorial film preparation method according to a fourth embodiment of the present disclosure;

FIGS. 14a and 14b show stage diagrams of a combinatorial film preparation method according to a fifth embodiment of the present disclosure;

FIGS. 15a to 15c show stage diagrams of a combinatorial film preparation method according to a sixth embodiment of the present disclosure;

FIG. 16 shows a schematic diagram of a combinatorial film preparation method according to a seventh embodiment of the present disclosure.

### DETAILED DESCRIPTION OF THE INVENTION

The following is a more detailed description of the present invention with reference to the accompanying drawings. In all the drawings, the same elements are denoted by similar reference numerals. For clarity, the parts in the drawings are not drawn to scale. In addition, some well-known parts may not be shown. For the sake of brevity, a semiconductor structure obtained after several steps may be described in a single drawing.

It should be understood that when describing the structure of a device, if a layer or a region is referred to as being “above” or “on” another layer or another region, it can mean directly above/on the other layer or region, or it can mean that there are other layers or regions between them. Moreover, if the device is flipped, that layer or region will be “below” or “under” the other layer or region.

If the situation of being directly above/on another layer or region is to be described, the expression “directly on . . . ” or “on . . . and adjacent to it” will be used in this text.

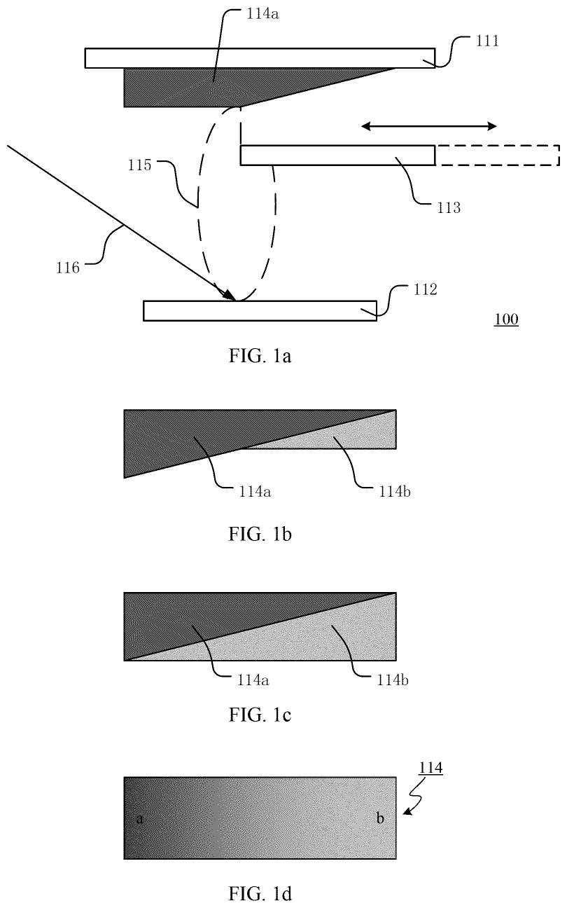

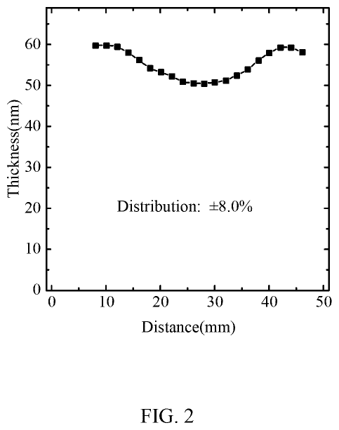

FIG. 1a to FIG. 1d illustrate a combinatorial film preparation method and device according to an existing technology; FIG. 2 shows a thickness distribution diagram of the combinatorial film according to the existing technology.

As shown in FIG. 1a to FIG. 1d, in the existing technology, the combinatorial film preparation device 100 includes a substrate 111 and a first target material 112 set opposite to each other. A mask 113 is placed between the substrate 111 and the first target material 112. When the laser beam 116 bombards the first target material 112, a plume 115 is formed. The plume 115 deposits on the surface of the substrate 111 opposite to the first target material 112 to form the first film 114a. In this process, by moving the mask 113, part of the plume 115 is blocked from contacting the surface of the substrate 111, resulting in a linear thickness variation in the formed first film 114a.

For example, the mask 113 initially is located outside the edge of the first target material 112 and the substrate 111 (as shown by the dashed line in FIG. 1a). After the laser beam 116 bombards the first target material 112, the mask 113 moves uniformly from one side of the substrate 111 to the other side. During this process, part of the surface of the substrate 111 is blocked and cannot form the first film 114a. When the mask 113 moves to block the entire surface of the substrate 111, it stops. The second target material 112 is then replaced, and the laser beam 116 continues to bombard the second target material 112. The mask 113 then continues to move in a straight line, beginning to expose part of the surface of the substrate 111, thus starting to form the second film 114b, until it reaches the other side of the substrate 111. A third film including the first film 114a and the second film 114b is formed on the surface of the substrate 111. The third film is then annealed to allow the components of the first film 114a and the second film 114b to intermingle, forming the combinatorial film 114, as shown in FIG. 1d.

In the final combinatorial film 114, for example, on the far left, the content of material a from the first target material 112 is 100%, and the content of material b from the second target material 112 is 0%. On the far right, the content of material a is 0%, and the content of material b is 100%. From left to right, the content of material a decreases linearly, while the content of material b increases linearly.

However, in this combinatorial film preparation method, since materials a and b are deposited alternately, time is required to replace the target material after one type of material has been deposited, thus reducing the deposition rate. Additionally, during the deposition of the same material, the mask 113 needs to move to block part of the surface of the substrate 111. Therefore, during the movement of the mask 113, thermal interference is caused to the substrate, causing the already deposited film 114 to undergo repeated annealing. At the same time, the process of replacing the target material also leads to temperature changes in the already deposited film, resulting in non-linear content variations in the final combinatorial film and reducing the performance of the combinatorial film.

Furthermore, in existing technologies, when depositing single-material films or combinations over a large area, due to the rotation of the substrate and/or target material, as well as the scanning path of the laser beam, the resulting film exhibits uneven thickness. As shown in FIG. 2, the thickness of the film varies in different deposition areas of the substrate due to various factors, and compensation for the film thickness is required to obtain a uniform film.

The inventors of the present application provide an apparatus and a method for pulsed laser deposition that can effectively solve the above problems.

The following is a detailed description of the specific implementation of the present invention in combination with the drawings and examples.

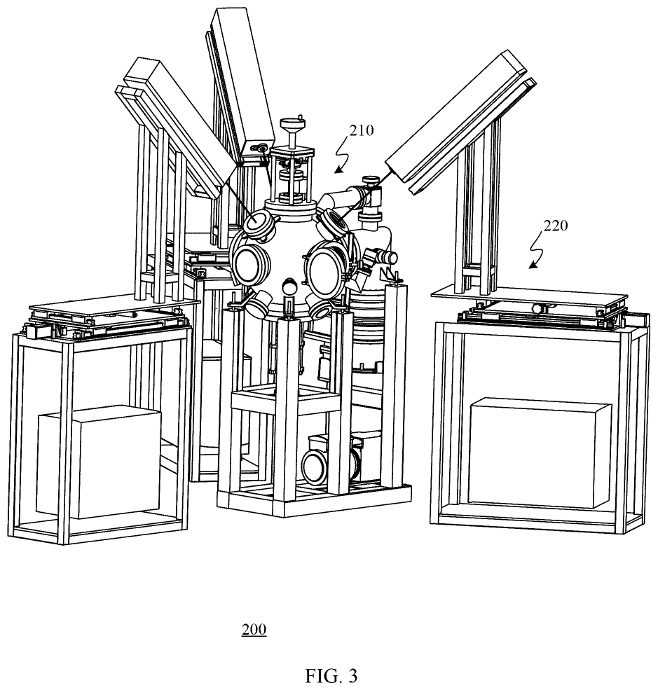

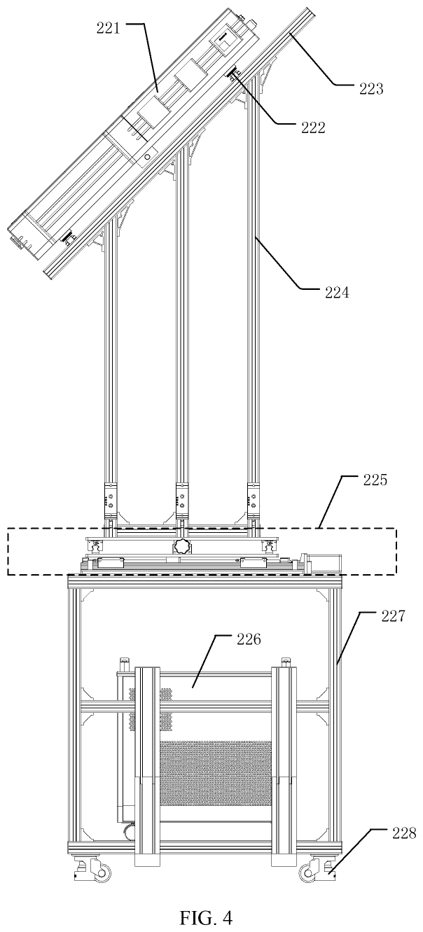

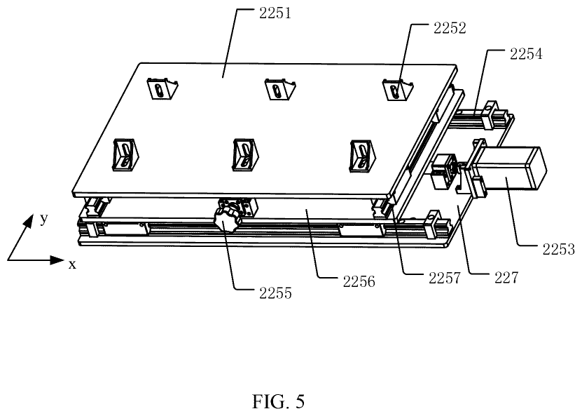

FIG. 3 shows a three-dimensional view of an apparatus for pulsed laser deposition according to an embodiment of the present disclosure; FIG. 4 shows a side view of a laser scanning sputtering component according to an embodiment of the present disclosure; FIG. 5 shows an adjustment device of the laser scanning sputtering component according to an embodiment of the present disclosure.

Referring to FIG. 3, the apparatus 200 for pulsed laser deposition according to an embodiment of the present disclosure includes: a deposition device 210 and multiple laser scanning sputtering components 220, FIG. 3 shows an embodiment with three laser scanning sputtering components 220.

In this embodiment, the deposition device 210 (refer to FIG. 6) includes: a reaction chamber 212, multiple first windows 211 on the side wall of the reaction chamber 212, a second window (not shown in the figure), used to support the reaction chamber 212 bracket, a motor group 216 located outside the reaction chamber 212, and a vacuum structure. Wherein, the first windows 211 are laser beam entry windows, and the second window, for example, is an observation window. The motor group 216 is used to drive the heating stage and the substrate inside the reaction chamber 212 to rotate, as well as to drive the fixed stage and the target material inside the reaction chamber to rotate, and the vacuum structure is used to evacuate the inside of the reaction chamber to maintain the vacuum pressure inside the reaction chamber.

Furthermore, referring to FIG. 4, each laser scanning sputtering component 220 includes: a laser 221, a first fixing part 222, a first support 223, a second support 224, an adjustment device 225, and a base.

The first support 223 is a planar support structure, and the bottom of the laser 221 is fixedly connected to one surface of the first support 223 through the first fixing part 222, that is, the first support 223 is used to fix and support the laser 221. In this embodiment, the laser 221 also has an indicator light, which is located near the laser beam outlet of the laser 221 and can produce an indicator light beam parallel to the laser beam. This indicator light beam is used for adjusting the height and tilt of the laser 221, so that the adjustment of the laser 221 is appropriate.

The second support 224 is a vertical support structure, fixedly connected to the other surface of the first support 223, in which the second support 224 includes multiple adjustable supports that extend vertically. By adjusting the extension and retraction of the adjustable supports at different positions of the second support 224, the surface height and tilt of the first support 223 can be adjusted, thereby adjusting the horizontal height and tilt of the laser 221.

The adjustment device 225 is a planar adjustment structure, located at the other end of the second support 224, and fixedly connected to the second support 224. The adjustment device 225 has a driving structure for changing the position and direction of the second support 224, the first support 223, and the laser 221.

The base is located below the adjustment device 225, and generally has a rectangular prism structure, including a support frame 227. An upper surface of the support frame 227 is fixedly connected to a lower surface of the adjustment device 225, on the one hand, for carrying the adjustment device 225, the second support 224, the first support 223, and the laser 221, and on the other hand, for providing a height for the laser 221.

In this embodiment, the specific structure of the adjustment device 225 is shown in FIG. 5, which includes a first plate 2251, a second plate 2256, a fastener 2252, a first sliding member 2257, and a second sliding member 2254.

The fastener 2252 includes multiple, fixed on the upper surface of the first plate 2251, and the fastener 2252 is used to fix the bottom of the second support 224 to the adjustment device 225. In this embodiment, for example, there are six fasteners 2252, and there are also six adjustable supports of the second support 224.

The first sliding member 2257 is located between the first plate 2251 and the second plate 2256, being slidable and used for fixing the first plate 2251 and the second plate 2256, while enabling the first plate 2251 and the second plate 2256 to move relatively in the horizontal plane along the extension direction of the first sliding member 2257. The second sliding member 2254 is located between the second plate 2256 and the upper surface of the support frame 227, being slidable and used for fixing the second plate 2256 and the upper surface of the support frame 227, while enabling the second plate 2256 and the support frame 227 to move relatively in the horizontal plane along the extension direction of the second sliding member 2254. The extension directions of the first sliding member 2257 and the second sliding member 2254 are perpendicular.

In this embodiment, the extension direction of the first sliding member 2257 is the first direction, for example, the y direction, and the extension direction of the second sliding member 2254 is the second direction, for example, the x direction, and the first direction and the second direction are perpendicular to each other. Since the adjustment device 225 is connected to the laser 221 through the second support 224 and the first support 223, moving the first plate 2251 along the first direction of the first sliding member 2257, the laser 221 will also move along the first direction; moving the second plate 2256 along the second direction of the second sliding member 2254, the laser 221 will also move along the second direction. In addition, the extension direction of the adjustable supports of the second support 224 is the third direction, for example, the z direction, and the third direction is perpendicular to the first direction and the second direction.

Furthermore, the adjustment device 225 also includes a first adjustment member 2255 and a second adjustment member 2253. The first adjustment member 2255 is located between the first plate 2251 and the second plate 2256, connected to the first sliding member 2257, and is used for controlling the high-precision displacement scanning control of the first plate 2251 relative to the second plate 2256 along the first direction. The second adjustment member 2253 is located between the second plate 2256 and the upper surface of the support frame 227, connected to the second sliding member 2254, and is used for controlling the high-precision displacement scanning control of the second plate 2256 relative to the support frame 227 along the second direction.

In this embodiment, the first adjustment member 2255 and the second adjustment member 2253, for example, are each a high-precision precision motor, respectively used for controlling the automated displacement scanning control of the adjustment device 225 along the first direction and the second direction. Furthermore, the displacement, the scanning path, the time for the first adjustment member 2255 and the second adjustment member 2253 can also be changed by modifying a program, thereby changing the displacement, the scanning path, the time for the laser 221.

Furthermore, the adjustment device 225 can also include a third adjustment member (not shown in the figure), which is connected to the second support 224 and is used for controlling the length of the multiple adjustable supports of the second support 224 in the third direction, thereby adjusting the tilt angle of the first support 223 and the laser 221, the third adjustment member, for example, is a high-precision precision motor. In other embodiments, a fourth adjustment member (not shown in the figure) can also be set on the multiple adjustable supports of the second support 224, and the fourth adjustment member controls the length of the multiple adjustable supports of the second support 224 in the third direction, the fourth adjustment member, for example, is a threaded knob.

Furthermore, referring to FIG. 4, each laser scanning sputtering component 220 also includes: a laser power supply 226, and the base also includes wheels 228. Wherein, the laser power supply 226 is located in the support frame 227, on the one hand, for providing power to the laser 221, and on the other hand, for increasing the weight of the lower part of the laser scanning sputtering component 220, changing the center of gravity of the laser scanning sputtering component 220, making the laser scanning sputtering component 220 less likely to tip over and suffer other issues; the wheels 228 are located around the bottom of the support frame 227, enabling the entire laser scanning sputtering component 220 to move. In addition, each wheel 228 may have an open state and a locked state, in the open state, the entire laser scanning sputtering component 220 can be pushed to a predetermined position; in the locked state, the wheel 228 cannot move, allowing the laser scanning sputtering component 220 to stay in the predetermined position.

Using the apparatus for pulsed laser deposition provided according to the present application, a single-material film can be deposited, and a combinatorial film can also be deposited. In the following embodiments of this application, an implementation for preparing a combinatorial film will be described.

FIG. 6 shows a schematic diagram of the pulsed laser deposition method according to an embodiment of the present disclosure.

The apparatus 200 for pulsed laser deposition according to an embodiment of the present disclosure is shown in FIG. 3, including a deposition device 210 and a laser scanning sputtering component 220. The pulsed deposition method of this apparatus 200 for pulsed laser deposition refers to FIG. 6, in which FIG. 6 also shows part of the structure inside the reaction chamber 212 of the deposition device 210. Referring to FIG. 6, the deposition device 210 includes: a reaction chamber 212, a substrate holder, a target holder 233, a window 211, and a motor group 216.

In the reaction chamber 212, it includes a substrate 321, at least one target material 331, and a target holder 233 for installing the target material 331 and a substrate holder (not shown in the figure) for installing the substrate 321. The motor group 216 is connected to the target holder 233 and/or the substrate holder, and is used to control the relative movement of the target holder 233 and the substrate holder, specifically, for example, the target holder 233 or the substrate holder moves reciprocatingly in a straight line. At the same time, the motor group 216 is also used to control the target material 331 fixed on the target holder 233 to rotate around the center of the target material 331. Multiple inclined fixed lasers 221 (only two are shown in the figure) emit laser beams that enter the reaction chamber 212 through the focusing mirror and the window 211 on the reaction chamber 212 and irradiate the target material 331. At a high energy density and in a short pulse time, the target material 331 absorbs the laser beam energy and rapidly increases the temperature of the spot to above the evaporation temperature of the target material 331, causing high temperature and ablation, and the target material 331 is vaporized and sputtered. Atoms, molecules, electrons, ions, and molecular clusters and micrometer-scale droplets, solid particles, etc., are sputtered from the surface of the target material 331, forming a localized high-temperature and high-density plasma 332. The plasma 332 forms a large temperature and pressure gradient in the direction of the normal line of the target material 331 and expands in that direction, forming a plasma plume 332 along the normal line direction of the target material 331. The high-energy ions in the plasma plume 332 bombard the surface of the substrate 321, causing atomic sputtering, thereby forming a film on the surface of the substrate 321. In this embodiment, a heater (not shown in the figure) is also included in the substrate holder in the substrate 321, which is used to heat the substrate 321 to the reaction temperature.

In this embodiment, the laser 221 moves relatively to the target material 331, allowing the spot formed by the laser beam on the surface of the target material 331 to scan the surface of the target material 331. Wherein, in the implementation where the laser 221 moves relatively to the target material 331, it can be the laser 221 or the target material 331 that moves reciprocatingly in a straight line, while the target material 331 rotates around its center, allowing the spot formed by the laser beam on the target material 331 to scan the surface of the target material 331 in a radial direction. Furthermore, since the target material 331 itself is rotating around its center, the entire surface of the target material 331 will be scanned by the laser beam during the movement process of the laser beam on the surface of the target material 331. To ensure that the surface of the target material 331 is uniformly scanned by the laser beam, the scanning speed of the laser beam along the center of the target material 331 to the edge can be controlled to be slower, and furthermore, by cooperating with the relative movement of the mask 333 and the substrate 321, a combinatorial film can be formed on the surface of the substrate 321.

In the embodiment shown in FIG. 6, the target holder 233, for example, is a large fixed plate with at least one mounting point, which can install at least one target material 331, and when multiple target materials 331 are used, their materials can be different, such as material a and material b. FIG. 6 shows a case of using two target materials, in which a mask 333 is set between the first target material 331a and the second target material 331b, one end of the mask 333 is connected to the target holder 233, and the other end extends vertically to a position near the surface of the substrate 321 to separate the multiple deposition areas of the target material 331. Two lasers 221 may be used to generate laser beams that bombard the first target material 331a and the second target material 331b, respectively, and the two lasers can be enabled simultaneously or alternately.

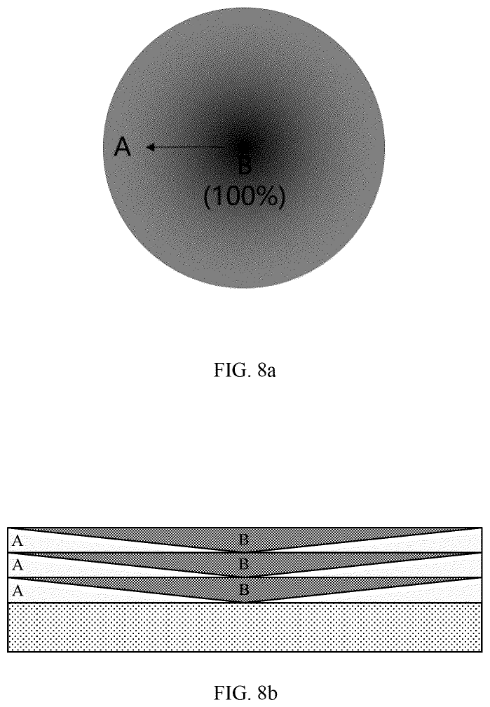

In one embodiment, the two lasers 221, for example, are alternately enabled, so when one laser 221 irradiates the first target material 331a, the mask 333 moves relatively to the substrate 321 in the direction of the second target material 331b; when the other laser 221 irradiates the second target material 331b, the mask 333 moves relatively to the substrate 321 in the direction of the first target material 331a, and when the mask 333 reciprocates, the area of the first deposition area corresponding to the surface of the substrate 321 and the first target material 331a first increases and then decreases. In this process, the deposition time at different positions of the first deposition area is different, thus the first film with gradient change can be formed. Correspondingly, the second deposition area can form the second film with gradient change, thereby forming a third film (refer to FIG. 8b) including the first film of material a and the second film of material b on the surface of the substrate 321, and the thickness of the two materials changes along the gradient. Specifically, the deposition thickness change of the first film and the second film can be controlled by controlling the relative movement speed between the mask 333 and the substrate 321, therefore, the component change of the final combinatorial film can be linear or non-linear, and technicians in this field can control the relative movement speed between the mask 333 and the substrate 321 according to the specific situation of the combinatorial film.

During the preparation of the combinatorial film, on one hand, the mask 333 is used to prevent mutual contamination of adjacent target materials, and on the other hand, the mask 333 is also used to block part of the plasma plume, dividing the surface of the substrate 321 into different deposition areas, and different components are deposited by controlling the deposition time for different deposition areas, making the material change of the final formed combinatorial film gradient.

In this embodiment, the reaction chamber 212 also includes multiple sensors (not shown in the figure) for monitoring the vacuum pressure, film deposition thickness, substrate heating temperature, etc., in the reaction chamber, thereby better controlling the reaction conditions and the extent of the reaction.

Furthermore, in some other embodiments, multiple mounting points are set on the target holder 233, and multiple target materials of different materials can be selected and installed on the target holder 233 according to the specific situation of the combinatorial film to be prepared, and the multiple different materials of the target materials are distributed in a straight line, with a mask arranged between adjacent target materials to prevent mutual contamination.

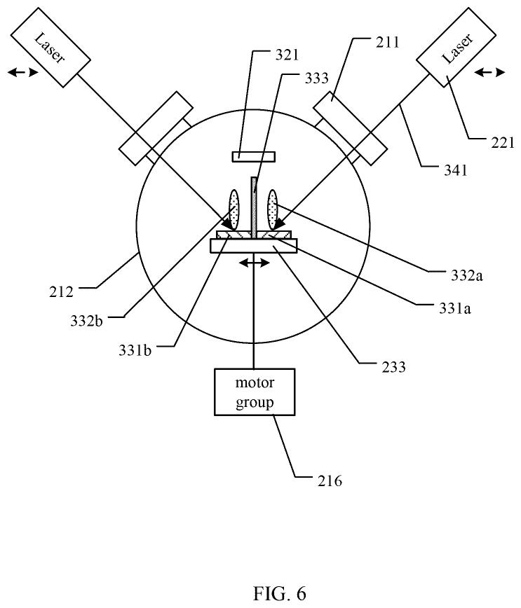

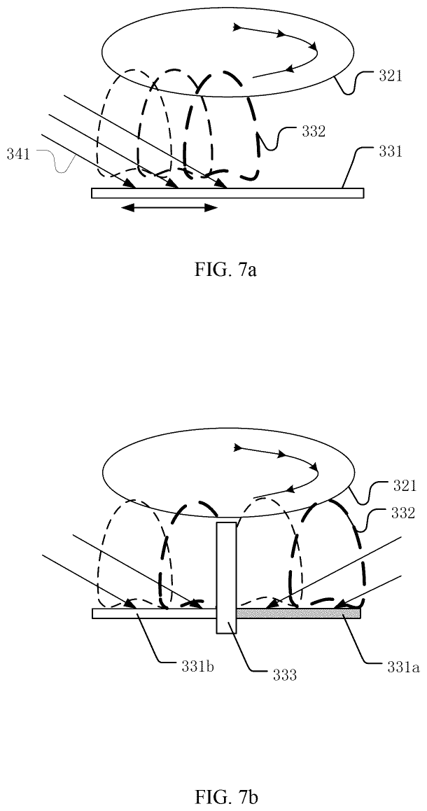

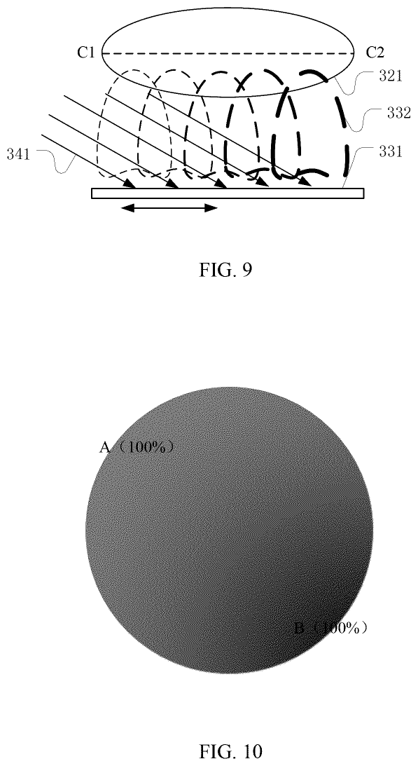

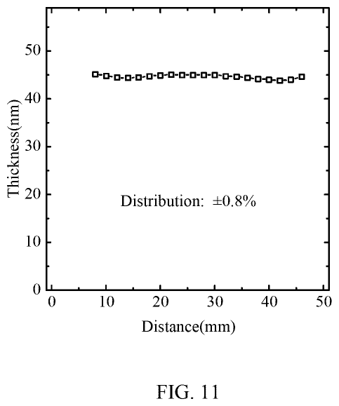

FIGS. 7a and 7b show the deposition diagram of the combinatorial film in the first embodiment of the present disclosure; FIGS. 8a and 8b show the top view and cross-sectional view of the combinatorial film in the first embodiment of the present disclosure; FIG. 9 shows the deposition diagram of the combinatorial film in the second embodiment of the present disclosure; FIG. 10 shows the top view of the combinatorial film in the second embodiment of the present disclosure; FIG. 11 shows the thickness distribution diagram of the combinatorial film in the embodiment of the present disclosure.

Referring to FIG. 7a, in the first embodiment, the target material 331, for example, is material B. During the preparation of the combinatorial film, the substrate 321 rotates uniformly around the center, and the target material 331 also rotates uniformly around the center, and the laser beam 341 produced by the laser 221 forms a spot on the surface of the target material 331 and reciprocates along the radius of the target material 331. Therefore, the plasma plume 332 formed by the laser beam irradiating the target material 331 forms a film on the surface of the substrate 321.

Furthermore, to form a combinatorial film with a material gradient change, the scanning time or scanning rate of the laser beam irradiating the center area of the target material 331 can be controlled to be long, that is, the time taken to scan the same distance in this area is long, and the scanning rate of the laser beam irradiating the target material 331 decreases gradually from the center to the edge, thus a film with thickness gradually decreasing from the center to the edge of the substrate can be obtained. For example, in FIGS. 7a and 7b, the thickness of the plasma plume 332 is represented by the thickness of the lines of the laser beam 341, the thicker the line, the longer the scanning time, and the thinner the line, the shorter the scanning time.

In this embodiment, the movement pattern of the substrate 321 rotating around the center includes movement direction and movement speed. Wherein, the movement direction includes: clockwise rotating direction, counterclockwise rotating direction; the movement speed includes: uniform rotating speed, non-uniform rotating speed. In the embodiment shown in FIG. 7a, the substrate 321, for example, is moved in uniform rotation along clockwise direction.

In the embodiment shown in FIG. 7a, the deposition is implemented by using, for example, material B. After replacing the target material 331 with material A, by modifying the scanning rate of the laser beam 341 on the surface of the target material, the combinatorial film as shown in FIG. 8a and FIG. 8b can be obtained. Wherein, when depositing material A, the laser beam 341 reciprocates along the radius of the target material 331, and the scanning rate of the laser beam 341 decreases gradually from the edge to the center along the direction from the edge to the center of the target material 331, forming a film A with a thicker edge and a thinner center as shown in FIG. 8b; then, after replacing the target material with material B, the scanning rate of the laser beam on the surface of the target material 331 is changed to be opposite to that of material A, thus obtaining a film B with a thickness change opposite to film A, and films A and B diffuse to form a combinatorial film.

Furthermore, referring to FIG. 7b, a deposition method for forming a combinatorial film using multiple lasers and multiple target materials simultaneously is shown. Wherein, multiple target materials 331 are installed on the target holder, and adjacent target materials 331 are isolated by a mask 333.

In the embodiment shown in FIG. 7b, the substrate 321 rotates around the center, the diameter of multiple target materials 331 is not less than the radius of the substrate 321, and the projection of multiple target materials 331 on the substrate 321 covers at least from the center to the edge of the substrate 321.

During the deposition of the first embodiment of the combinatorial film, multiple target materials 331 with different components are used, and the mask 333 is used to isolate adjacent target materials 331 and prevent contamination of the target materials. When multiple laser beams are used simultaneously or alternately to bombard the corresponding target materials, the scanning rate of the corresponding laser beams on the surface of the target materials also varies according to the different components of the target materials, thereby changing the deposition time for different deposition areas on the substrate 321.

Referring to FIG. 7b, the target material 331a, for example, is material A, and the target material 331b, for example, is material B. During the preparation of the combinatorial film in the first embodiment, the scanning time of the laser beam on the target material 331a is long at a position far from the center of the substrate 321, and the scanning rate gradually decreases along the direction from the edge of the substrate to the center, and a film A with a thicker edge and a thinner center can be formed on the surface of the substrate 321 when the substrate 321 rotates. Similarly, the scanning time of the laser beam on the target material 331b is short at a position far from the center of the substrate 321, and the scanning rate gradually increases along the direction from the edge of the substrate to the center, and a film B with a thinner edge and a thicker center can be formed on the surface of the substrate 321 when the substrate 321 rotates.

FIGS. 8a and 8b respectively show a schematic diagram of forming the combinatorial film of the first embodiment. By controlling the scanning rate of the laser beam on the scanning path to change the deposition time for different deposition areas on the substrate, a combinatorial film with thickness continuously changing on the surface of the substrate can be formed, and the thickness uniformity of the combinatorial film can also be precisely controlled by controlling the scanning rate of the laser beam, thereby improving the performance of the film.

In some other embodiments, the scanning path of the laser beam on the surface of the target material can be in any direction on the surface of the target material, or the scanning path of the laser beam on the surface of the target material can be in multiple directions on the surface of the target material, that is, the scanning path of the laser beam can be changed; furthermore, the scanning rate of the scanning path of the laser beam on the surface of the target material can be at least one of an increasing rate or a decreasing rate, while cooperating with the rotation of the substrate, the combinatorial film preparation method according to this application can theoretically be in any direction.

FIGS. 9 and 10 show the preparation diagram of the combinatorial film in the second embodiment of the present disclosure. Compared with the first embodiment, in the combinatorial film of the second embodiment, materials A and B have thickness gradient changes along a diameter of the substrate.

Referring to FIG. 9, during the deposition of the combinatorial film in the second embodiment, the substrate 321 remains stationary, and the scanning path and scanning rate of the laser beam on the surface of the target material 331 are controlled to form the combinatorial film. Wherein, when depositing material B, for example, on the diameter C1-C2 of the substrate 321, at the target material 331 corresponding to point C1, the laser beam scanning time is controlled to be short, thus the thickness of material B deposited at the point C1 of the substrate 321 is small, and as the scanning time of the laser beam increases along the C1 to C2 direction, the thickness change of the deposited film is achieved.

In this embodiment, taking an area corresponding to point C2 of the substrate 321 as a deposition area with the longest deposition time, by controlling the scanning rate of the laser beam, the deposited film B is realized as a film with point C2 as the center, and the thickness of the film B decreases outward from the center. Furthermore, when depositing material A, for example, the scanning time of the laser beam is controlled to be opposite to that when depositing material B, thus obtaining a film A with point C1 as the center, and the thickness decreases outward from the center.

The combinatorial film composed of film A and film B is annealed to obtain a combinatorial film with gradually changing content of material A and material B as shown in FIG. 10.

Furthermore, FIG. 11 shows the thickness distribution diagram of the combinatorial film in the embodiment of the present disclosure. Compared with the thickness curve diagram of the existing technology (refer to FIG. 2), in this application, since the scanning rate of the laser beam scanning is controlled, the deposition time for different deposition areas on the substrate is different, thus forming the film A and/or the film B with thickness variation. During the deposition process, if the film is found to be uneven in thickness, the scanning rate of the laser beam on the corresponding area of the target material surface can be adjusted to adjust the film thickness, thereby improving the uniformity of film deposition.

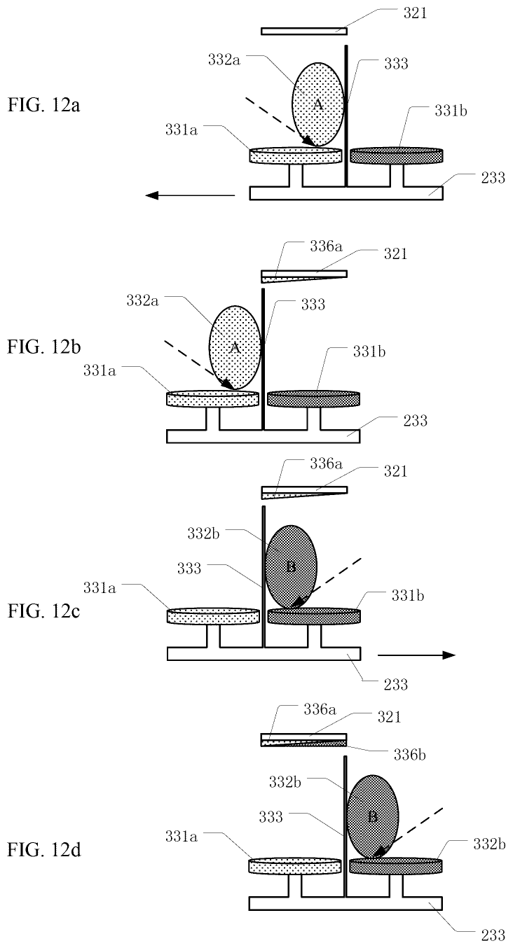

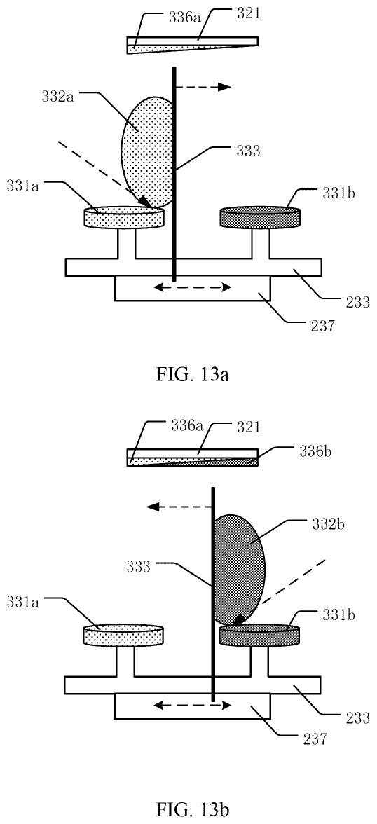

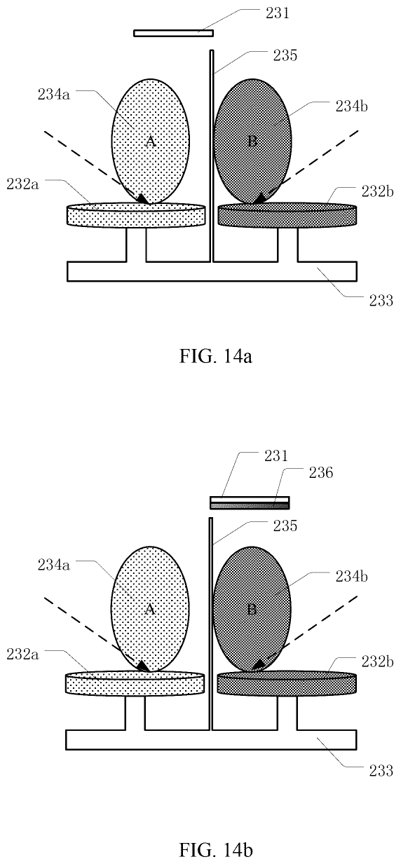

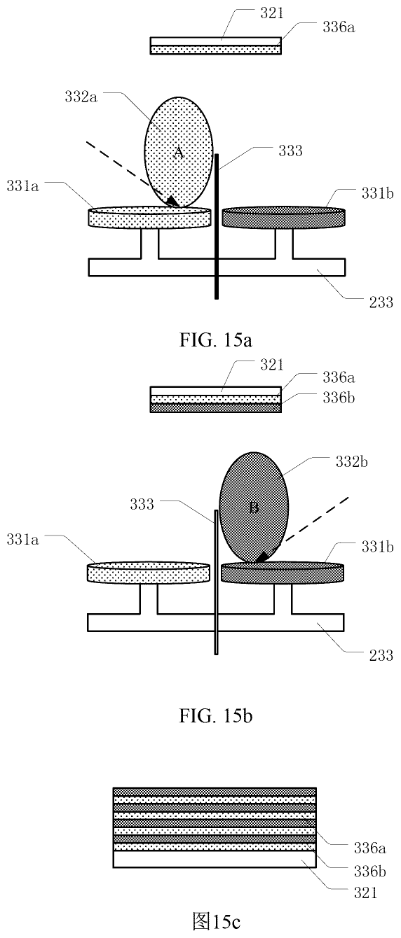

FIGS. 12a to 12d show the stage diagrams of the combinatorial film preparation method according to the third embodiment of the present disclosure; FIGS. 13a and 13b show the stage diagrams of the combinatorial film preparation method according to the fourth embodiment of the present disclosure; FIGS. 14a and 14b show the stage diagrams of the combinatorial film preparation method according to the fifth embodiment of the present disclosure; FIGS. 15a to 15c show the stage diagrams of the combinatorial film preparation method according to the sixth embodiment of the present disclosure. Compared with the deposition method of the second embodiment, in the deposition methods of the third, fourth, and fifth embodiments, the target stage and/or the substrate stage are moved.

In the third embodiment shown in FIGS. 12a to 12b, the mask 333 is fixedly connected to the target holder 233, and the mask 333 is moved relative to the substrate 321 by moving the target holder 233. Wherein, the two lasers, for example, are alternately enabled to alternately generate laser beams bombarding the first target material 331a and the second target material 332b.

Referring to FIG. 12a, in an initial stage, the substrate 321 is opposite to the first target material 331a made of material a. At this time, the laser 221(a) corresponding to the first target material 331a is enabled to generate a laser beam irradiating the first target material 331a and producing the first plasma plume 332a. The mask 333 is set between the first target material 331a and the second target material 331b, and extends vertically between the target material surface, dividing the surface of the substrate 321 into multiple deposition areas. Therefore, the first plasma plume 332a generated by the laser beam bombarding the first target material 331a will not contaminate the second target material 331b, and the mask 333 makes the different areas of the surface of the substrate 321 have different times to be positioned as a deposition area, thereby depositing the same material with different contents in different areas, thus forming a combinatorial film with linearly varying content on the surface of the substrate 321.

Furthermore, the target holder 233 can be moved along a direction towards the first target material 331a from the second target material 331b, and the first target material 331a and the second target material 331b move together with the target holder 233 until the second target material 331b is opposite to the position of the substrate 321, forming the first film 336a with gradient distribution on the surface of the substrate 321, as shown in FIG. 12b.

In this step, the surface of the substrate 321 facing the first target material 331a is in contact with the first plasma plume 332a for a longer time, so the thickness of this side of the first film 336a is larger. In addition, since the target holder 233 moves at a constant speed, and the mask 333 blocks part of the first plasma plume 332a from diffusing towards the second target material 331b, which is in a non-deposition area, the formed first film 336a has a thickness that linearly decreases (continuously changes) in the direction from the first target material 331a to the second target material 331b.

Furthermore, stop using the laser 221(a) corresponding to the first target material 331a, and enable the laser 221(b) corresponding to the second target material 331b, and move the target holder 233 and the target material in the direction from the first target material 331a to the second target material 331b, as shown in FIGS. 12c and 12d.

In this step, the laser beam irradiates the second target material 331b to produce the second plasma plume 332b and forms the second film 336b on the surface of the substrate 321. At the same time, due to the movement of the second target material 331b and the shielding of the mask 333, the formed second film 336b has a larger thickness on the surface of the substrate 321 at a side corresponding to the second target material 331b. In addition, due to the uniform movement of the second target material 331b, the thickness of the formed second film 336b changes linearly (continuously).

Furthermore, annealing the first film 336a and the second film 336b is also performed to form a third film 336 (combinatorial film) of mixed components of the first film 336a and the second film 336b.

In another embodiment, film growth of materials a and b can also be achieved by moving the substrate.

In the embodiment shown in FIGS. 12a to 12d, since the plasma plumes 332 generated by the laser beam bombarding the first target material 331a and the second target material 331b can be seamlessly connected, the time for replacing the target material during the combinatorial film preparation can be saved, and the preparation rate of the combinatorial film can be improved.

Furthermore, during the entire film preparation process, changes in the reaction chamber 212 are only the movement of the target material and the alternation of the plasma plume, and there will be no pauses and thermal interference caused by the replacement of the target material and the movement of the mask in the film preparation process, so the content variation of the combinatorial film formed by this method is more linear, and the performance is also improved.

Furthermore, the mask 333 is located between two target materials and extends in a direction perpendicular to the target material surface, which can not only reduce the mutual influence between the two target materials but also limit the range of the plasma plume to some extent, making the thickness variation of the deposited film more linear.

FIGS. 13a and 13b show the stage diagrams of the combinatorial film preparation method according to the fourth embodiment of the present disclosure. Compared with the third embodiment, in the fourth embodiment, only the mask 333 is moved to achieve the preparation of the combinatorial film, and lasers are enabled alternately to generate corresponding laser beams.

In this embodiment, referring to FIGS. 13a and 13b, on the target holder 233, there is also a control structure 237, and the mask 333 is connected to the control structure 237, and the control structure 237 is used to control the reciprocating motion of the mask 333.

Wherein, the target materials 331a and 331b are respectively located at positions corresponding to the substrate 231, that is, the plasma plume 332 generated by the laser beam bombarding the target materials can be deposited on the surface of the substrate 321 to form a film, as shown in FIG. 13a, when the laser beam bombards the first target material 331a, by moving the mask 333 by the control structure 237 (along the direction of the dashed line in the figure), an area of the first deposition area corresponding to the first target material 331a changes, so the deposition time at different positions of the first deposition area is different, forming the first film 336a with gradient change. And by moving the mask in an opposite direction, the area of the second deposition area corresponding to the second target material 331b changes, forming the second film 336b.

In this embodiment, only by moving the mask 333, the deposition time for different deposition areas is controlled. To avoid mutual contamination between adjacent target materials, for example, target materials with smaller area can be selected, so that the distance between adjacent target materials can be set further apart, making it not easy to cause contamination of the target materials. In some other embodiments, for example, the shape of the mask 333 near the target material can be changed, for example, a lower part of the mask can be made of elastic material. During the movement of the mask 333, the elastic material can wrap the target material, but an upper part of the mask remains vertical, so that even if the adjacent target materials are close, the mask 333 can protect other target materials from being contaminated during the movement process. Those skilled in the art should be able to think of changing the structural shape of the mask 333 near the target material 331 to prevent adjacent target materials from being contaminated.

FIGS. 14a and 14b show the stage diagrams of the combinatorial film preparation method according to the fifth embodiment of the present disclosure. Compared with the third and fourth embodiments, in the fifth embodiment, for example, the substrate 321 is moved, and two lasers are used to bombard two target materials to generate two plasma plumes for film deposition.

Referring to FIGS. 14a and 14b, two lasers 221 are enabled at the same time, respectively bombarding the first target material 331a and the second target material 331b to generate plasma plumes 332a and 332b. By moving the substrate 321 reciprocatingly, a combinatorial film 336 with two materials diffusing each other is formed on the surface of the substrate 321.

In this embodiment, since the two materials are deposited at the same time, they will diffuse with each other during the deposition process, thereby increasing the diffusion effect of the combinatorial film and improving the performance of the combinatorial film.

Furthermore, compared with the third embodiment, in the combinatorial film preparation method of the fifth embodiment, the two materials are deposited at the same time, which further increases the preparation rate of the combinatorial film and reduces the time cost.

In other embodiments, the combinatorial film can also be prepared by moving the substrate 321.

FIGS. 15a to 15c show the stage diagrams of the combinatorial film preparation method according to the sixth embodiment of the present disclosure. Compared with the third to fifth embodiments, the sixth embodiment is a multi-layer heterojunction combinatorial film with two materials deposited alternately, and the thickness of each layer of material remains the same.

In this embodiment, referring to FIGS. 15a and 15b, the mask 222 between the first target material 331a and the second target material 331b is lowered by a portion, so that the mask 333 is only used to prevent mutual contamination between the two target materials. Then, two lasers 221 are enabled alternately to generate plasma plumes 332a and 332b, and deposit them on the surface of the substrate 321 to form a combinatorial film with material a and material b stacked alternately (as shown in FIG. 15c).

In this embodiment, by moving the target material and/or the substrate, a uniform and efficient combinatorial film is formed on the surface of the substrate 321.

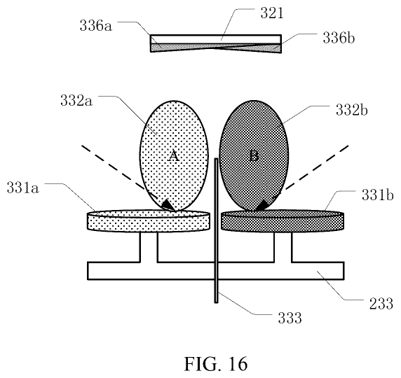

FIG. 16 shows a schematic diagram of the combinatorial film preparation method according to the seventh embodiment of the present disclosure. Compared with other embodiments, the seventh embodiment shows a schematic diagram of co-sputtering free diffusion for preparing a combinatorial film.

Referring to the embodiment shown in FIG. 16, two lasers 221 can also be enabled at the same time to generate corresponding plasma plumes 332a and 332b, and deposit them on the surface of the substrate 321 to form a combinatorial film of material a and material b. In this embodiment, since material a and material b are deposited at the same time, the two materials will diffuse with each other during the deposition process, thereby increasing the diffusion effect of the combinatorial film and improving the performance of the combinatorial film.

According to the apparatus for pulsed laser deposition provided by the present disclosure, the laser scanning sputtering component uses an adjustable support to fix the laser, which can change the incidence direction of the laser (including the incidence angle and the incidence position), thereby directly irradiating the target material in the reaction chamber for thin film deposition. The extremely simple straight light path greatly reduces the loss of laser energy, and the “overall moving scanning” working mode of the laser light path component provides extremely high stability and consistency for laser scanning sputtering.

Furthermore, the laser may be a small solid-state laser with a small volume and light weight. The laser with low power used in this application can reduce the cost of the equipment and also reduce the volume of the equipment.

In the laser scanning sputtering component of this application, due to the use of a small laser, the weight of the entire laser scanning sputtering component is very small, which allows the entire laser scanning sputtering component to be conveniently controlled in a predetermined direction with an automated high-precision displacement scanning control through the assembly of high-precision precision motors. In addition, since the laser can use a small solid-state laser weighing about 25 kilograms, the process of controlling the laser to move in the first direction and the second direction through the adjustment device is also more convenient, which can also improve the consistency of laser energy at different scanning points on the target material surface during the scanning process.

Furthermore, in the laser scanning sputtering component of this application, the laser is equipped with an indicator light that can produce an indicator light beam, which is convenient for adjusting the tilt angle and moving direction of the laser.

Furthermore, the modular design of the laser scanning sputtering component not only has higher technical compatibility and flexibility but also achieves the purpose of quick assembly and disassembly of the entire system.

Furthermore, according to the apparatus for pulsed laser deposition and method provided by the present disclosure, in the process of depositing a combinatorial film or a thin film with large area, by controlling the scanning rate of the laser beam scanning the target material, the deposition time for different deposition areas on the substrate can be controlled, thereby controlling the thickness distribution of the film, compensating for the deposition of thinner parts of the film, and thus improving the performance of the film.

Furthermore, using the method for pulsed laser deposition in this application, various combinatorial films can be formed, including a combinatorial film with thickness gradients changing along the radial direction of the substrate, as well as a combinatorial film with thickness gradients changing in other directions. At the same time, by controlling the scanning rate of the laser beam scanning the target material through the laser scanning sputtering component, the thickness distribution of the combinatorial film can be controlled, and the performance of the combinatorial film can be improved.

Furthermore, according to the apparatus for pulsed laser deposition provided by the present disclosure, the target holder can hold one or more target materials. Multiple target materials are placed side by side, with multiple laser beams and masks placed vertically between adjacent target materials. By controlling the relative movement of the mask and the substrate, the materials of multiple target materials can be alternately deposited on the substrate to form a combinatorial film, or multiple materials can be deposited at the same time to form a combinatorial film, thereby saving the time for replacing target materials and improving the performance of the combinatorial film.

Furthermore, in this application, the mask located between the target materials forms side walls on the target holder to separate the plasma plumes formed by multiple target materials, preventing mutual contamination between the two target materials. Moreover, the mask can extend to the vicinity of the substrate holder, dividing the substrate into multiple different deposition areas. By controlling the relative movement of the mask and the substrate, the deposition time for different deposition areas can be different, as well as controlling the diffusion range of the plasma plume, making the content variation of the formed combinatorial film show a gradient change, thereby improving the performance of the combinatorial film.

Furthermore, the mask extends vertically from the substrate surface, and during the process of forming the deposited material of different components of multiple target materials on the substrate surface, the mask will not be located between the target material and the substrate. Therefore, the combinatorial film prepared by this application greatly reduces the thermal interference situation brought by the mask parallel to the substrate surface during the movement process in the existing technology, thereby improving the performance of the combinatorial film.

Furthermore, based on the miniaturization of the laser scanning sputtering component according to the present disclosure, it is also possible to use multiple lasers to bombard the target material at the same time to form a combinatorial film. In the preparation process of a combinatorial film, the components of various materials begin to diffuse, making the diffusion of various components in the formed combinatorial film more uniform.

Furthermore, the apparatus and the method for pulsed laser deposition according to the present disclosure can also meet requirements for the preparation of combinatorial films with component gradients by co-sputtering methods with multiple target materials (three or more). By retracting the mask vertical to the adjacent target materials or increasing the distance between the mask and the substrate holder, in addition, the method of alternating sputtering deposition can also be used to prepare a multi-layer heterojunction superlattice combinatorial film. Therefore, the present disclosure can not only manufacture single-component uniform films, multi-layer structure films, and various types of combinatorial films, but also improve efficiency and quality.

As described in the embodiments of the present disclosure, these embodiments do not exhaustively describe all the details, nor do they limit the invention to only the specific embodiments described. Obviously, many modifications and variations can be made based on the above description. The specification selects and specifically describes these embodiments to better explain the principles and practical applications of the invention, so that technicians in the technical field can make good use of the invention and modifications based on the invention. The invention is only limited by the claims and their entire scope and equivalents.

1. An apparatus for pulsed laser deposition, comprising a deposition device and a plurality of laser scanning sputtering components, wherein the laser scanning sputtering component includes:
a base;
an adjustment device, disposed on the base;
a plurality of second supports, disposed on the adjustment device, extending in a third direction;
a first support, disposed on the plurality of second supports;
wherein the adjustment device is configured to adjust the second supports and the first support to move in a first direction and/or a second direction, the first direction, the second direction, and the third direction are mutually perpendicular to each other.

2. The apparatus according to claim 1, wherein the adjustment device comprises:
a first plate and a second plate;
a fastener, fixed on the first plate, for fixing the second supports and the adjustment device;
a first sliding member, being slidable and fixing the first plate and the second plate, located between the first plate and the second plate, to enable the first plate and the second plate to move relatively in the first direction;
a second sliding member, being slidable and fixing the second plate and the base, located between the second plate and the base, to enable the second plate and the base to move relatively in the second direction.

3. The apparatus according to claim 2, wherein the adjustment device further includes:
a first adjustment member, connected to the first sliding member, for controlling the first plate and the second plate to move relatively in the first direction with high-precision automated displacement scanning;
a second adjustment member, connected to the second sliding member, for controlling the second plate and the base to move relatively in the second direction with high-precision automated displacement scanning.

4. The apparatus according to claim 1, wherein the plurality of second supports are adjustable supports.

5. The apparatus according to claim 4, wherein the adjustment device further comprises:
a third adjustment member, connected to the second supports, for adjusting a length of the second supports in the third direction to adjust a tilt angle of the first support.

6. The apparatus according to claim 4, wherein the plurality of second supports are equipped with a fourth adjustment member, for adjusting a length of the second supports in the third direction to adjust a tilt angle of the first support.

7. The apparatus according to claim 5, wherein the first adjustment member, the second adjustment member, and/or the third adjustment member include a high-precision precision motor.

8. The apparatus according to claim 7, wherein the first adjustment member, the second adjustment member, and/or the third adjustment member are used to control a scanning path and a scanning rate of a laser beam, generated by a laser, on a target material.

9. The apparatus according to claim 1, wherein the deposition device comprises:
a reaction chamber, a target holder and a substrate holder, wherein the target holder and the substrate holder are set opposite to each other inside the reaction chamber, the target holder is used for installing a target material, and the substrate holder is used for installing a substrate,
wherein the laser scanning sputtering components are configured to control the scanning rate of a laser beam on a scanning path to change deposition time for different deposition areas on the substrate, thereby controlling a content of a deposited material corresponding to a component of the target material on different deposition areas of the substrate.

10. The apparatus according to claim 9, wherein the target holder is equipped with a plurality of target materials, components of deposited materials of the plurality of target materials are the same or different,
wherein a mask is set on the target holder, the mask forms a side wall on the target holder to separate plumes generated by adjacent ones of the plurality of target materials during sputtering, the mask extends to a vicinity of the substrate holder to separate different deposition areas of the substrate,
wherein the mask and the substrate holder move relatively to change exposure deposition time for different deposition areas of the substrate, thereby controlling the content of the deposited material corresponding to different components of the plurality of target materials on different deposition areas of the substrate, thus forming a combinatorial film of the components of the deposited materials of the plurality of target materials on the substrate.

11. The apparatus according to claim 10, wherein the combinatorial film comprises: a combinatorial film with deposited material components varying in a linear gradient or a non-linear gradient; and a multi-layer heterojunction combinatorial film with deposited material components deposited alternately.

12. The apparatus according to claim 11, wherein the deposition device further comprises:
a control structure, one end of which is fixedly connected to the target holder and the other end is connected to the mask, for controlling the mask to move relatively to the substrate holder.

13. The apparatus according to claim 12, wherein the target holder and the substrate holder are stationary, and the mask is moved to change the deposition time for different deposition areas of the substrate; or the target holder and the mask are stationary, and the substrate holder is moved to change the deposition time for different deposition areas of the substrate.

14. The apparatus according to claim 13, wherein the mask moves reciprocally in a gradient changing direction of the deposited material components; or the substrate holder moves reciprocally in a gradient changing direction of deposited material components.

15. The apparatus according to claim 12, wherein the control structure is further configured to control the mask to move in a direction perpendicular to a surface of the substrate.

16. The apparatus according to claim 11, wherein the substrate holder is stationary, and the target holder is moved, driving the mask to move to change the deposition time for different deposition areas of the substrate.

17. The apparatus according to claim 16, wherein the target holder moves reciprocally in a gradient changing direction of the deposited material components.

18. (canceled)

19. (canceled)

20. The apparatus according to claim 1, further comprising:
a laser, disposed on the first support, for generating a laser beam.

21. (canceled)

22. The apparatus according to claim 20, wherein the laser beam generated by the laser has wavelengths including 1064 nm, 532 nm, 355 nm, 266 nm, and different wavelengths can be automatically selected and switched; or a plurality of lasers are alternately activated or simultaneously activated to serve as the laser generating the laser beam.

23. (canceled)

24. The apparatus according to claim 9, wherein the deposition device further comprises:
a motor group, located outside the reaction chamber, connected to the target holder and the substrate holder, for controlling movements of the target holder and the substrate holder.

25. The apparatus according to claim 24, wherein the motor group is configured to control the target material to rotate around its center to change a spot position of the laser beam on the target material.

26-42. (canceled)
